(19) United States
(12) Patent Application Publication
(10) Pub. No.: US 2026/0186029 A1
(43) Pub. Date: Jul. 2, 2026

(54) Combined Non-Contact Voltage and Current Detector

(71) Applicant: James Chun, Vista, CA (US)

(72) Inventor: James Chun, Vista, CA (US)

(21) Appl. No.: 19/002,221

(22) Filed: Dec. 26, 2024

(51) Int. Cl. G01R 15/20; G01R 31/382

(52) U.S. Cl. CPC G01R 15/202; G01R 31/382

(57) ABSTRACT

A non-contact voltage and current detector feature an elongated hollow housing containing a voltage-detecting circuit, a current-detecting circuit, a microprocessor, a software program, a key switch, and a battery source. Mounted on the housing is a flashlight and an audio source. When the key switch is pressed, a test program confirms the battery source has sufficiently charged, and the two detecting circuits are operating. When the key switch is pressed, the voltage-detecting circuit is energized and illuminates a voltage-detecting LED mounted on the detector's elongated body to indicate the presence of an AC voltage in a conductor when brought in proximity. The current-detecting circuit includes two or more current-detecting LEDs also mounted on the housing to display variations in the detected current signal. The microprocessor includes a timer function that turns off the detector at a selected interval.

### FIELD OF THE INVENTION

This invention pertains to non-contact voltage detectors and non-contact current detectors, and more particularly, detectors in which the voltage and current detectors are combined into a single housing.

### BACKGROUND OF THE INVENTION

Electricians and homeowners commonly use non-contact voltage detectors (called NCVDs) to detect voltages in wires, outlets, switches, junction boxes, circuit breakers making them suitable for different jobs. They are especially useful for quickly verifying if circuits have been de-energized before starting maintenance or repairs.

Today, small, pocket-sized NCVDs are commonly used because they can be carried in a pocket, a tool belt, or a pouch, making them easily accessible and reducing the need to retrieve larger or more complex tools. They usually have thin, elongated, probe-like bodies that can be held and operated on by one hand. Voltage-detecting sensors are located at one end keeping the user a safe distance away from live circuits. They also have single-button operations, making them easy to use by homeowners or less experienced users, and have audible beeps and flashing LEDs that identify live circuits in noisy or dark environments.

Electrical panels and subpanels are usually found in tight, dark spaces. Sometimes, the panels and subpanels are elevated and require the worker to work on ladders. When working in an electrical subpanel, the worker would use an NCVD described above to ensure no live voltage in the panel. He may also want to check for current flow issues, such as ground fault conditions, using a separate device known as a current detector. Current detectors are large devices with claws that must be placed around a conductor if a current is present.

A tool that combines the functions of a NCVD and a current detector would allow the electrician and homeowner to access the presence of voltage and current simultaneously. A tool with combined functions would allow the worker to make a faster, more complete diagnostic picture of an electrical system. A tool with combined functions would be easier to carry and operate in tight dark spaces.

### SUMMARY OF THE INVENTION

A non-contact AC voltage and AC current detector features an elongated hollow body containing an elongated printed circuit board connected to an AC voltage-detection circuit, an AC current-detecting circuit, and a microprocessor. The printed circuit board is connected to a battery source located inside the housing. Mounted on the surface of the housing and connected to the printed circuit board is a manual switch that allows the user to selectively activate and deactivate the detector and to select between an AC voltage-detecting operating mode and an AC current-detecting operating mode.

Mounted on the tip of the housing is a pair of hall sensors configured to detect AC voltage and AC current flowing in a conductor when the tip is brought in proximity to the conductor. When the manual switch is activated, the hall sensors are energized to continuously detect and respond to magnetic fields produced by the conductor. The user uses the manual switch to activate either the AC voltage-sensing circuit or the AC current-detection circuit. The voltage-detecting circuit includes at least one first LED mounted on the housing which is illuminated in one of two colors to indicate the presence or absence of voltage. The current-detecting circuit includes two or more second LEDs also mounted on the housing arranged in a bar graph format in which the LEDs are illuminated according to the current detected. The number of LEDs illuminated corresponds to the current detected.

Also mounted on the housing and connected to the printed circuit board is a flashlight which is automatically illuminated when the detector is activated by a key switch. In one embodiment, the microprocessor on the printed circuit board may be programmed so that the key switch pressed and held for a selected amount of time, the flashlight may be turned OFF.

Located inside the housing is a sound-generating device that is activated when the main switch is initially activated thereby confirming the battery is sufficiently charged.

The flashlight remains activated until the switch is deactivated.

The microprocessor includes a timer function that turns off the detector at a selected interval.

### BRIEF DESCRIPTION OF DRAWINGS

FIG. 1 is a top perspective view of the detector in accordance with the disclosure.

FIG. 2 is a bottom perspective view of the detector shown in FIG. 1.

FIG. 3 is a top plan view of the detector shown in FIG. 1.

FIG. 4 is a side elevational view of the detector shown in FIG. 1.

FIG. 5 is a bottom plan view of the detector shown in FIG. 1.

FIG. 6 is a front elevational view of the detector shown in FIG. 1.

FIG. 7 is a rear elevational view of the detector shown in FIG. 1

FIG. 8 is an exploded view of the detector shown in FIG. 1.

FIG. 9 is a bottom plan view of the printed circuit board.

FIG. 10 is a side elevational view of the printed circuit board shown in FIG. 9

FIG. 11 is a top plan view of the printed circuit board shown in FIG. 10.

FIG. 12 is an enlarged sectional view of the tip showing the relative locations of the voltage detector LED, the two hall sensors, and the flashlight LED.

FIG. 13 is a diagram of the voltage-detecting circuit.

FIG. 14 is a diagram of the current-detecting circuit.

FIG. 15 is a flow diagram of the various power states for a detector in accordance with the disclosure.

### DETAILED DESCRIPTION OF THE INVENTION

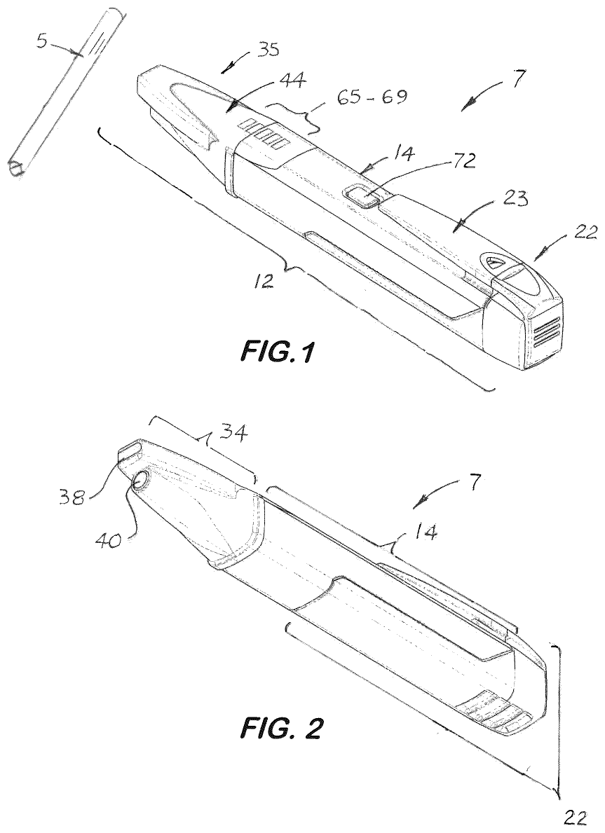

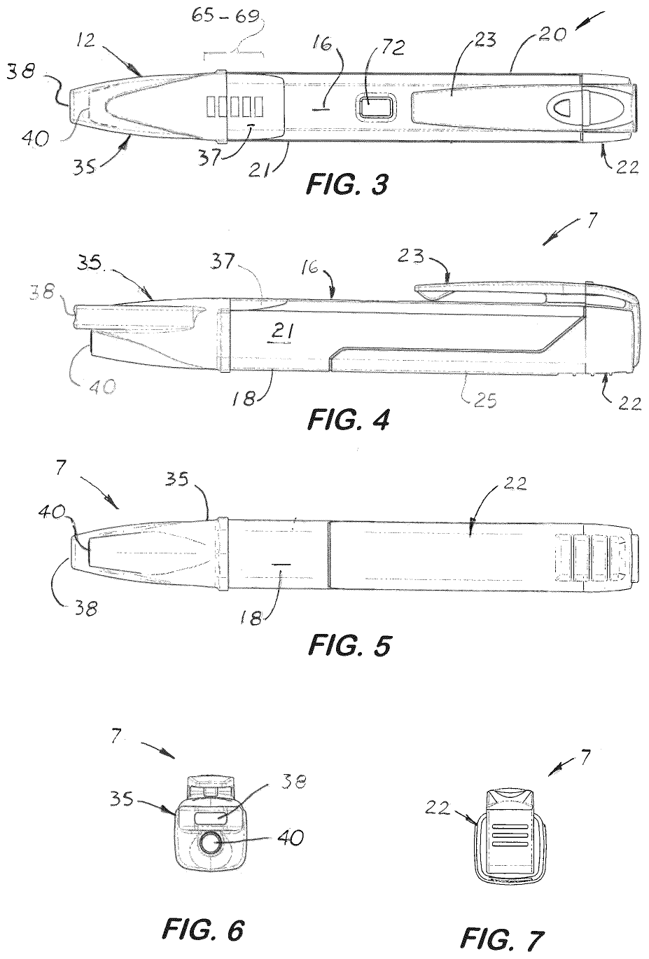

A non-contact AC voltage and AC current detector 7 is depicted in the accompanying figures. FIGS. 1 and 2 are top and bottom perspective views of detector 7 that includes a hollow elongated body 12 comprising an intermediate section 14, with an end cap 22 attached at one end and a tip cap 35 attached to the opposite end. Intermediate section 14 and the end cap section 22 are made of opaque material.

The intermediate body section 14 is a hollow structure with two opposite open ends, a top surface 16, a bottom surface 18, and two opposite side surfaces 20, 21. Formed on the bottom surface 18 under the middle and rear areas of the intermediate body section 14 is a slide receiver 19. Formed over the top surface 16 is an upper slot opening 15. Formed on the top surface 16 near the body section's midline axis is a key switch opening 32. Formed on the rear area of the top surface 16 is a raised, forward pocket clip component 23B. Formed on the bottom surface 18 is a slide receiver 19.

The end cap 22 has a hollow structure with a closed end and a lower, forward-extending slide member 25. The slide member 25 is configured to slide into the slide receiver 19 formed on the intermediate body section 14. Formed on the top surface of the end cap 22 is a rear pocket clip component 23A. When the end cap 22 is attached to the intermediate body section 14, the pocket clip component 23B and the pocket clip component are aligned, thereby forming a pocket clip 23 configured to attach to a pocket or belt. Formed on the pocket clip component 23A is a tongue 24 that engages a tongue hole 17 formed on the pocket clip component 23B to hold the intermediate body section 14 and end cap 22 together.

The tip cap 35 includes a closed, longitudinally aligned tapered nose 38. Located under tapered nose 38 is a flashlight opening 40. Formed on the top surface of the tip cap 35 is a raised hood section 44 that extends rearward and forms a projection 35 that extends into a slot opening 15 formed on the front end of the intermediate body section 14. Formed on the projection 34 are five LED openings 65-69. Formed on the tapered nose 38 is a flashlight opening 40.

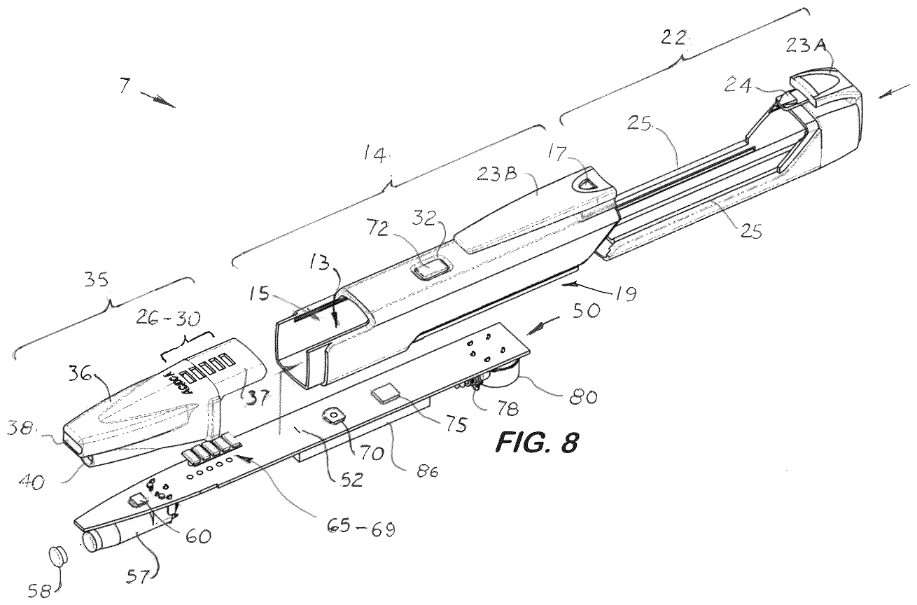

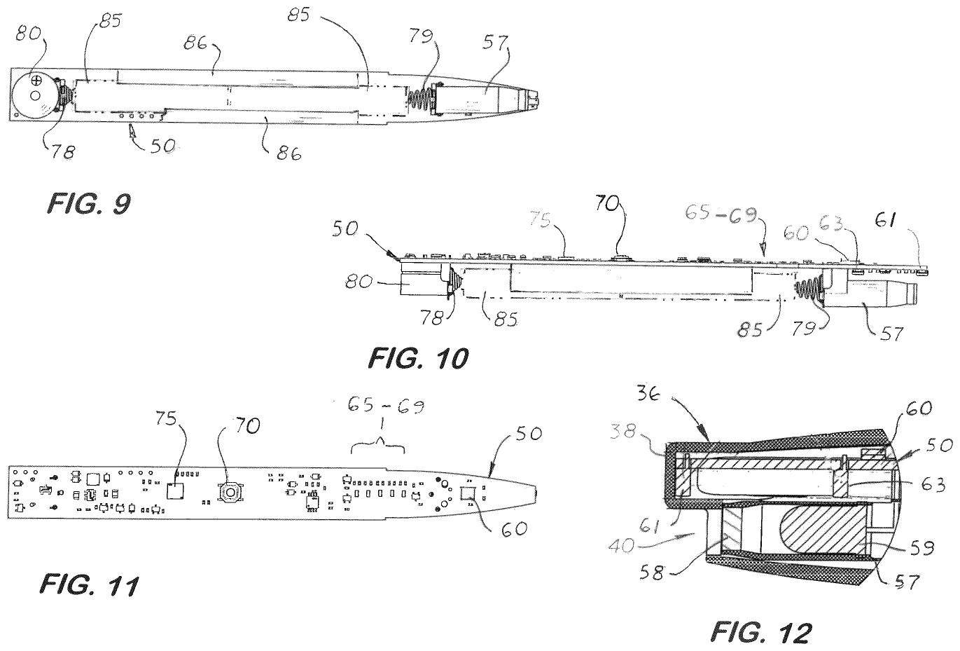

FIG. 8 depicts detector 7 in an exploded view that more clearly shows an elongated printed circuit board 50 designed to extend longitudinally and fit inside the hollow space 13 formed in the elongated body 12. Mounted on the bottom surface and near the front end of the printed circuit board 50 is an elongated flashlight shield 57. Extending downward from the printed circuit board 50 and into the flashlight shield 57 is a flashlight LED 59. Flashlight shield 57 is closed at one end and has an open flashlight opening 40 formed on its opposite end. Inserted into the flashlight opening 40 is lens 58. Located inside the shield 57 is a flashlight LED 59 that produces light when activated that shines through lens 58.

Mounted on the front area and extending downward from the printed circuit board 50 is a first hall sensor 61 and a second hall sensor 63. First hall sensor 61 is located near the end of the printed circuit board 50 to place the first hall sensor 61 near a conductor 5. The second hall sensor 63 is spaced apart (5 to 25 mm) from the first hall sensor 61 so that a magnetic current produced by conductor 5 may be sensed by the two hall sensors 61 and 63.

Formed under the printed circuit board 50 is a battery compartment area configured to hold a battery source. In the embodiment shown, the battery source is two AAA batteries 85 aligned in ‘in-series’ alignment, with the positive terminal on one battery connected to the negative terminal on the other. Mounted on and extending downward from the printed circuit board 50 on opposite ends of the battery compartment are two battery spring clips 78, 79. One battery spring clip 78 is mounted near the rear end of the printed circuit board 50, and the opposite battery spring clip 79 is attached to the inside wall of the flashlight shield. 57. Located in the battery compartment are two optional, longitudinally aligned battery pads 86 that keep the two batteries 84 longitudinally aligned. Attached to the rear end and extending downward from the printed circuit board 50 is an audio source 80, such as a buzzer or speaker.

Mounted on the top surface of the printed circuit board 50 is at least one voltage-indicating LED 60, two or more current-indicating LEDs (five shown referenced as 65-69), a key switch 70, a microprocessor 75, The voltage-indicating LED 60 is located near the front end of the printed circuit board 50. When assembled, when the LED 60 is activated, the raised hood section 44 and the adjacent areas on the end cap 38 are illuminated . . . The current-indicating LEDs 65-69 are aligned on the printed circuit board 50 so that they extend into the current LED holes 26-30 formed on the top surface of the elongated body 12. The key switch 70 is located near the midline axis and configured to be vertically aligned with the key switch opening 32 formed on the elongated body 12. An optional keypad 72 may be placed over the key switch 70 and extends through the key switch opening 32.

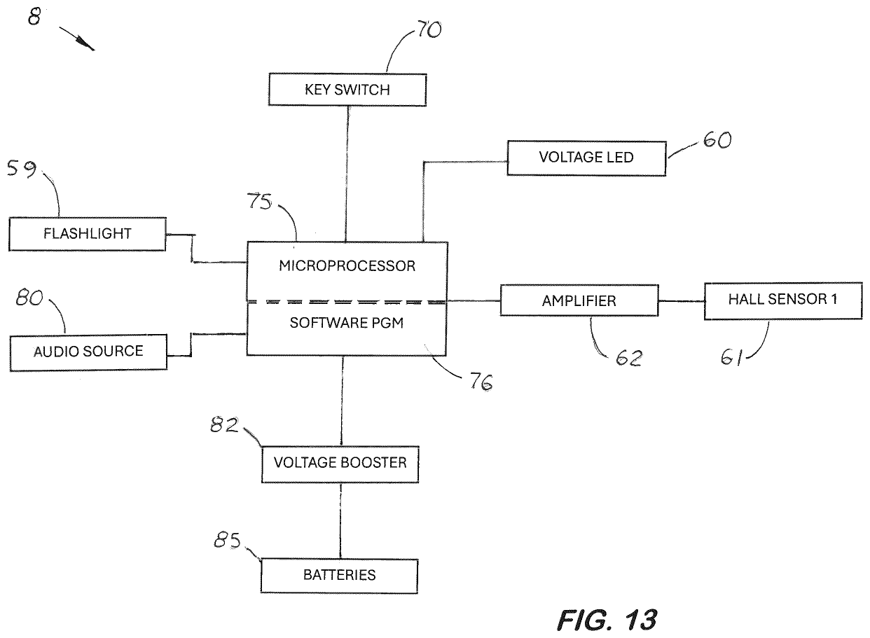

As shown more clearly in FIG. 13, detector 7 includes a voltage-detecting circuit 8 that includes a single hall sensor 1, the microprocessor 76 with a software program 76. Connected to the microprocessor 76 is the flashlight 59, the key switch 70 flashlight 59, the voltage-detecting LED 60 and batteries 85. A voltage booster 82 may be connected to the batteries 85 to increase their voltage. A first amplifier 62 is connected to the hall sensor 61 to increase the signal from the hall sensor 61.

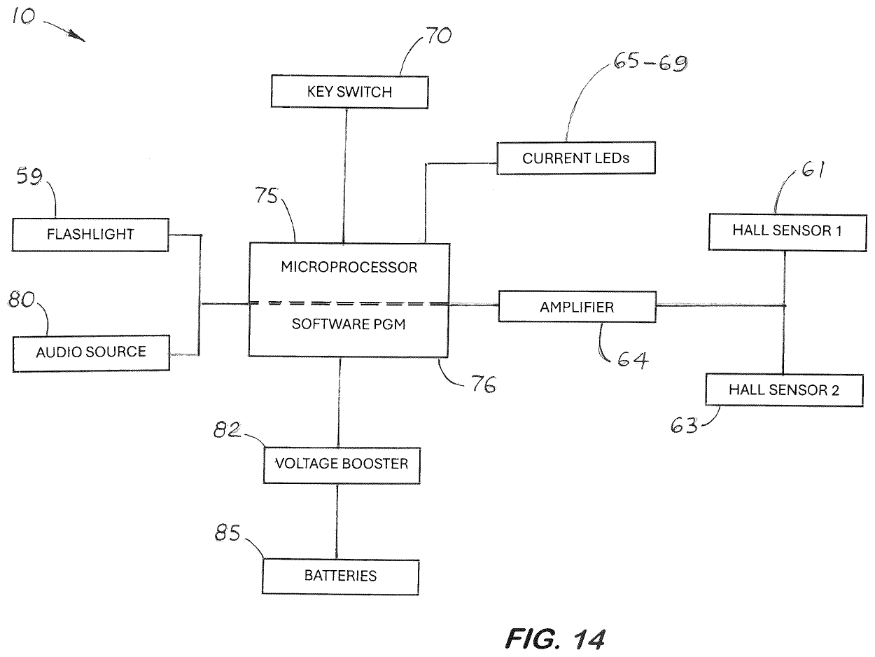

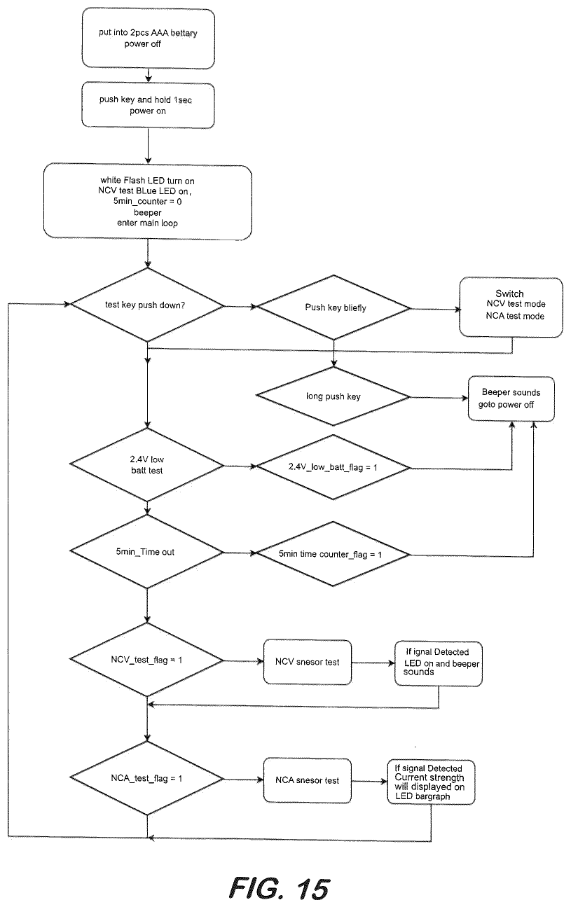

As shown more clearly in FIG. 14, detector 7 also includes a current-detecting circuit 10 that uses the first hall sensor 61 and a second hall sensor 63, and the microprocessor 76 with a software program 76. Connected to the microprocessor 76 is the flashlight 59, the key switch 70, and the batteries 85. Like the voltage-detecting circuit 8, a voltage booster 82 may be connected to the batteries 85 to increase the voltage from the batteries 85. The voltage booster 82 is configured to increase or boost the voltage from 3 volts to 4 volts. Either the first amplifier 62 shown in FIG. 13 or a second amplifier 64 shown in FIG. 14, is connected to the hall sensors 61, 63 to increase the signal from the hall sensors 61, 63.

### Operation

FIG. 15 is a flow diagram of the various power states for detector 7 in accordance with the disclosure. Two charged AAA batteries 85 are inserted into the detector's battery compartment. The key switch 70 is then pushed and held for 1 second to power ON the printed circuit board 50 and the microprocessor 75. When the key switch 70 is pressed, a test program is run which determines if the batteries 85 have sufficient charge. The test program also activates the flashlight LED 59 and the voltage-indicating LED 60. If the test program is successful, detector 7 automatically operates in a voltage-detecting mode and the flashlight LED 59 and voltage-indicating LED both remain lit. If the battery voltage is too low, the flashlight LED 59 and audio source 80 either remain off or are momentarily activated and then turn off. In addition to determining if the batteries 85 have sufficient charge, the microprocessor 75 also performs tests on the voltage-detecting circuit 8 and the current-detecting circuit 10. If the test program determines a fault exists in either circuits 8 or 10, then the flashlight LED 59 is not illuminated, and no audio signal is from the audio source 80. If the test program passes, then the voltage-detecting circuit 8, the flashlight LED 59, and the voltage-indicating LED 60 are activated. The voltage-indicating LED 60 turns GREEN and the audio source 80 produces a short beep. When the tapered nose 38 on the tip cap 35 is brought in proximity (within 1 to 2 inches) of conductor 5, the voltage-indicating LED 60 turns RED and a second beep is produced by the audio source when a voltage potential is detected in the conductor 5.

If the key switch 70 is pressed continuously for 3 to 5 seconds, the detector 7 enters current-detecting mode which activates the current-detecting circuit 10. After the key switch 70 has been pressed continuously, at least one current-indicating LED (65-69) is illuminated and the audio source 80 produces a short beep. When the current-detecting circuit 10 is activated, both hall sensors 61 and 63 are energized to continuously detect and respond to magnetic fields produced by the conductor 5. The current-detecting circuit includes five LEDs 65-69 mounted on the elongated body 12. When the tapered nose 38 is brought in proximity (within 1 to 2 inches) of a conduct 5, the current-indicating LEDs 65-69 are configured to illuminate in a bar graph format. The number of current-indicating LEDs 65-69 illuminated depends on the strength of the current detected in conductor 5. The number of current-indicating LEDs illuminated corresponds to the current detected. If no current is detected, then none (or only one) current-indicating LEDs are illuminated.

In one embodiment, the microprocessor 70 and software program 76 are configured to turn off the detector 7 when the key switch 70 pressed and held for a selected amount of time and after a pre-program amount of time when no activity is detected.

In compliance with the statute, the invention described has been described in language more or less specific as to structural features. It should be understood, however, that the invention is not limited to the specific features shown, since the means and construction shown comprises the preferred embodiments for putting the invention into effect. The invention is therefore claimed in its forms or modifications within the legitimate and valid scope of the amended claims, appropriately interpreted under the doctrine of equivalents.

I claim:

1. A voltage and current detector, comprising:
a. an elongated body with a tip cap;
b. a voltage-detecting circuit located inside said elongated body, said voltage-detecting circuit configured to detect voltage potential in a conductor when said tip cap is brought in close proximity to said conductor, said voltage-detecting circuit includes as least one voltage-indicating LED;
c. a current-detecting circuit located inside said elongated body, said current-detecting circuit configured to detect a current in said conductor when said tip cap is brought near said conductor, said current-detecting circuit includes at least two current-indicating LEDs;
d. a microprocessor connected to said voltage-detecting circuit and said current-detecting circuit;
e. a software program used to control said microprocessor and activate said voltage-detecting circuit and said current-detecting circuit;
f. a battery source connected to said microprocessor; and
g. a key switch connected to said microprocessor and used to control activation of said voltage-detecting circuit or said current-detecting circuit.

2. The voltage and current detector, as recited in claim 1, further includes a flashlight connected to said microprocessor and said battery.

3. The voltage and current detector, as recited in claim 2, wherein said microprocessor monitors an electrical charge in said battery and discontinues electrical power to said flashlight when said electrical charge is below a threshold electrical charge.

4. The voltage and current detector, as recited in claim 1, further includes an audio source connected to said microprocessor, said microprocessor configured to activate said audio source when a voltage is detected in said conductor by said voltage-detecting circuit.

5. The voltage and current detector, as recited in claim 4, further includes a flashlight connected to said microprocessor and said battery.

6. The voltage and current detector, as recited in claim 5, wherein said microprocessor senses a low battery level in said battery source and automatically prevents or discontinues electrical power to said flashlight.

7. The voltage and current detector, as recited in claim 1, wherein said software program is configured to cause illumination of said voltage indicating LED in one color when no voltage is detected in said conduct and causes said voltage-indicating LED to illuminate in a second color associated when a voltage is detected in said conductor.

8. The voltage and current detector, as recited in claim 3, wherein said software program is configured to cause illumination of said voltage-indicating LED in one color when no voltage is detected in said conduct and causes said voltage-indicating LED to illuminate in a second color associated when a voltage is detected in said conductor.

9. The voltage and current detector, as recited in claim 4, wherein said software program is configured to cause illumination of said voltage-indicating LED in one color when no voltage is detected in said conduct and causes said voltage-indicating LED to illuminate in a second color associated when a voltage is detected in said conductor.

10. The voltage and current detector, as recited in claim 1, wherein said current-detecting circuit includes said current LEDs are aligned in a side-by-side manner and configured to illuminate in a series and in a bar graph manner to indicate the strength of a detected current.

11. The voltage and current detector, as recited in claim 2, wherein said current-detecting circuit includes said current-indicating LEDs are aligned in a side-by-side manner and configured to illuminate in a series and in a bar graph manner to indicate the strength of a detected current.

12. The voltage and current detector, as recited in claim 3, wherein said current-detecting circuit includes said current-indicating LEDs are aligned in a side-by-side manner and configured to illuminate in a series and in a bar graph manner to indicate the strength of a detected current.

13. The voltage and current detector, as recited in claim 4, wherein said current-detecting circuit includes said current-indicating LEDs are aligned in a side-by-side manner and configured to illuminate in a series and in a bar graph manner to indicate the strength of a detected current.

14. The voltage and current detector, as recited in claim 7, wherein said current detection circuit includes a plurality of current-indicating LEDs aligned in a side-by-side manner, said current detection circuit configured to illuminate said current-indicating LEDs individually in a series and in a bar graph manner to indicate the strength of a detected current.

15. The voltage and current detector, as recited in claim 1, wherein said elongated body housing includes a tip hood containing hall sensors, said hall sensors configured to detect a magnetic field generated by the flow of current through a conductor.

16. The voltage and current detector, as recited in claim 4, wherein said housing includes a tip hood containing hall sensors, said hall sensors configured to detect a magnetic field generated by the flow of current through a conductor.

17. The voltage and current detector, as recited in claim 7, wherein said tip cap contains two hall sensors configured to detect a voltage potential and a magnetic field generated by the flow of current through said conductor.

18. The voltage and current detector, as recited in claim 10, wherein said tip cap contains two hall sensors configured to detect a voltage potential and a magnetic field generated by the flow of current through said conductor.

19. The voltage and current detector, as recited in claim 14, wherein said tip cap contains two hall sensors configured to detect voltage potential and a magnetic field generated by the flow of current through said conductor.

20. A voltage and current detector for detecting voltage or current in a conductor, comprising:
a. an elongated body that includes a tip cap;
b. at least one pair of all sensors located at said tip cap, said hall sensors configured to detect a voltage and current in a conductor when said tip cap is positioned in proximity of said conductor;
h. a flashlight mounted on said body and aimed forward from said tip cap;
i. a voltage-detecting circuit connected to one of said hall sensor and at least one voltage-indicating LED mounted on said elongated body, said voltage-detecting circuit configured to detect voltage in a conductor without contacting said conductor and activate said voltage-indicating LED;
j. a current-detecting circuit connected to said pair of hall sensors and a plurality of current-indicating LEDs mounted on said elongated body said current-detecting circuit configured to detect a current in said without contacting said conductor and activate said current-indicating LEDs, the number of said current-indicating LEDs activated according to the strength of said current detected;
k. a printed circuit board located in said elongated body;
l. a microprocessor mounted on said printed circuit board;
m. a software program used to control said microprocessor and activate said voltage-detecting circuit and said current-detecting circuit;
n. a key switch mounted on said printed circuit board and used to selectively control activation and deactivation of said voltage-detecting circuit and said current-detecting circuit; and
o. a battery source connected to said printed circuit board.
